(19) United States
(12) Patent Application Publication
(10) Pub. No.: US 2011/0215813 A1
(43) Pub. Date: Sep. 8, 2011

(54) FUEL PROPERTY SENSOR ABNORMALITY DETERMINING DEVICE

(75) Inventors: Mie Sasai, Susono-shi (JP); Kazuhiro Wakao, Susono-shi (JP)

(73) Assignee: Toyota Jidosha Kabushiki Kaisha, Toyota-Shi (JP)

(21) Appl. No.: 13/038,839

(22) Filed: Mar. 2, 2011

(30) Foreign Application Priority Data
Mar. 3, 2010 (JP) JP2010-046575

(51) Int. Cl. G01R 31/02

(52) U.S. Cl. 324/537

(57) ABSTRACT

A plurality of capacitance values at different obtained fuel temperatures are obtained. Ethanol concentrations of fuel to be measured are obtained from these capacitance values after correcting for an amount of change in the capacitance values due to a temperature characteristic. The correction according to the temperature characteristic is realized according to a map stored in a control apparatus. It is determined that there is an abnormality in an alcohol concentration sensor if the difference among the obtained ethanol concentrations is equal to or greater than a predetermined value.

### CROSS-REFERENCE TO RELATED APPLICATIONS

This application claims priority to Japanese Patent Application No. 2010-046575 filed on Mar. 3, 2010, which is incorporated herein by reference in its entirety including the specification, drawings and abstract.

### BACKGROUND OF THE INVENTION

1. Field of the Invention

The invention relates to a fuel property sensor abnormality determining device.

2. Description of the Related Art

Japanese Patent Application Publication No. 2009-191650 (JP-A-2009-191650), for example, describes technology related to an abnormality determination for a fuel property sensor. More specifically, JP-A-2009-191650 describes technology related to an abnormality determination for an alcohol concentration sensor. With the abnormality determining technology in JP-A-2009-191650, it is determined that there is an abnormality in the alcohol concentration if the output voltage of an alcohol concentration sensor is indicative of a value outside of a voltage range that corresponds to an alcohol concentration of 0% to 100%.

However, in the related art described above, if the output voltage of an alcohol concentration sensor is not indicative of a value outside of the voltage range that corresponds to an alcohol concentration of 0% to 100%, an abnormality of the alcohol concentration sensor will not be detected. Therefore, even if there is a difference between the output value of the alcohol concentration sensor and the alcohol concentration, the output value of the alcohol concentration sensor may be used as a normal value. As a result, with the abnormality determining method according to the related art described above, if a fuel property sensor is no longer indicating a correct fuel property, an incorrect sensor value may end up being used to control an internal combustion engine.

### SUMMARY OF INVENTION

The invention thus provides a fuel property sensor abnormality determining device capable of determining whether there is an abnormality, in which a correct value corresponding to a fuel property is unable to be output, in a fuel property sensor.

A first aspect of the invention relates to an abnormality determining device that determines an abnormality of a capacitance-type fuel property sensor having a detecting portion that detects a capacitance value of fuel to be measured. This abnormality determining device includes a fuel temperature identifying portion that obtains a temperature of the fuel to be measured at the detecting portion; an obtaining portion that obtains a plurality of the capacitance values at different obtained temperatures of the fuel to be measured; and a determining portion that determines whether there is an abnormality in the fuel property sensor based on whether the plurality of capacitance values obtained by the obtaining portion are following a temperature characteristic of a capacitance value at the fuel property sensor.

### BRIEF DESCRIPTION OF THE DRAWINGS

The foregoing and further objects, features and advantages of the invention will become apparent from the following description of preferred embodiments with reference to the accompanying drawings, wherein like numerals are used to represent like elements and wherein:

FIG. 1 is a view of the overall structure of a system that includes a fuel property sensor abnormality determining device according to a first example embodiment of the invention;

FIG. 2 is a view showing a frame format of the fundamental structure for detecting an alcohol concentration;

FIG. 3 is a chart showing the temperature characteristic of ethanol concentration and capacitance value;

FIG. 4 is a view showing a frame format of an example of a failure mode of a capacitance-type alcohol concentration sensor;

FIG. 5 is a more detailed view showing a frame format of a method for determining an abnormality of an alcohol concentration sensor according to the first example embodiment of the invention;

FIG. 6 is a flowchart of a routine executed by a control apparatus in the first example embodiment of the invention;

FIG. 7 is a flowchart of a routine executed by a control apparatus in the second example embodiment of the invention;

FIG. 8 is a flowchart of another routine executed by the control apparatus in the second example embodiment of the invention;

FIG. 9 is a flowchart of a routine executed by a control apparatus in a fourth example embodiment of the invention;

FIG. 10 is a flowchart of a routine executed by a control apparatus in a fifth example embodiment of the invention;

FIG. 11 is a flowchart of a routine executed by a control apparatus in a sixth example embodiment of the invention; and

FIG. 12 is a flowchart of a routine executed by a control apparatus in a seventh example embodiment of the invention.

### DETAILED DESCRIPTION OF THE PREFERRED EMBODIMENTS

### First Example Embodiment

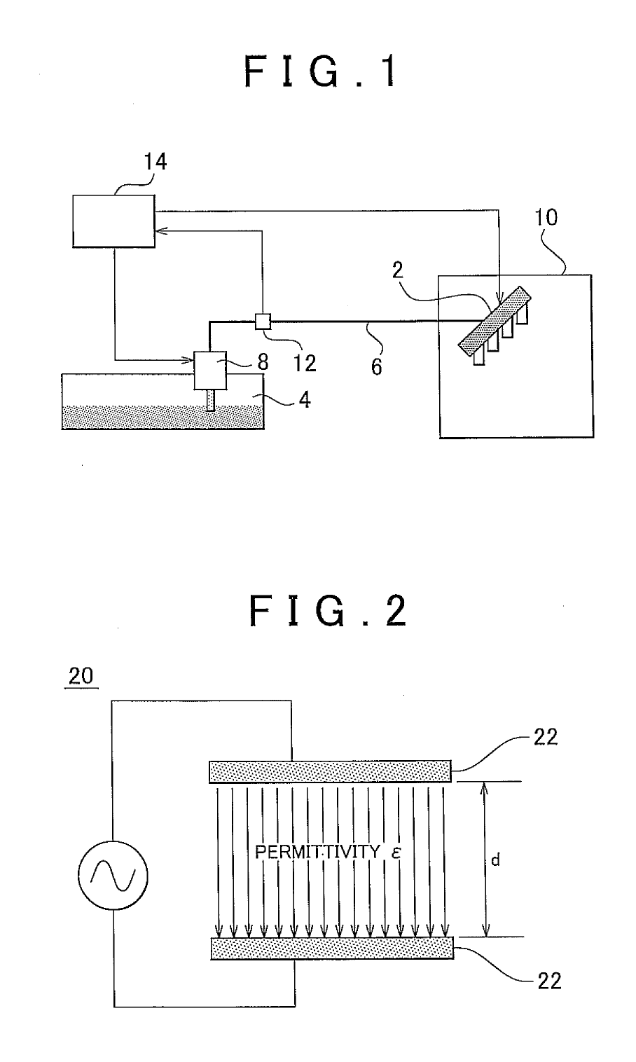

FIG. 1 is a view of the structure of a system that includes a fuel property sensor abnormality determining device according to a first example embodiment of the invention. The system in FIG. 1 is applied to an internal combustion engine to which fuel containing alcohol is supplied. For example, the system configuration according to the first example embodiment can be applied to a vehicular internal combustion engine mounted in a so-called flexible fuel vehicle (FFV). Incidentally, in the description below, an ethanol blended fuel is used.

The system in FIG. 1 includes an internal combustion engine 10 that has a plurality of cylinders. The system in FIG. 1 also includes injectors 2 (i.e., fuel injection valves) for supplying fuel into the cylinders of the internal combustion engine 10, and a fuel tank 4 in which the fuel is stored. The injectors 2 and the fuel tank 4 are connected together by a fuel line 6. A fuel pump 8 is disposed in this fuel line 6, and enables the fuel inside the fuel tank 4 to be delivered to the injectors 2 at a predetermined flowrate. Also, an alcohol concentration sensor 12 that issues an output indicative of the ethanol concentration is arranged downstream of the fuel pump 8 in the fuel line 6.

The system in FIG. 1 also includes a control apparatus 14. This control apparatus 14 is electrically connected to the alcohol concentration sensor 12, and detects the ethanol concentration by receiving the output from the alcohol concentration sensor 12. The control apparatus 14 is also electrically connected to the fuel pump 8 and the injectors 2. The control apparatus 14 controls the fuel flowrate and the fuel injection quantity of the injectors 2 by outputting control signals to the fuel pump 8 and the injectors 2.

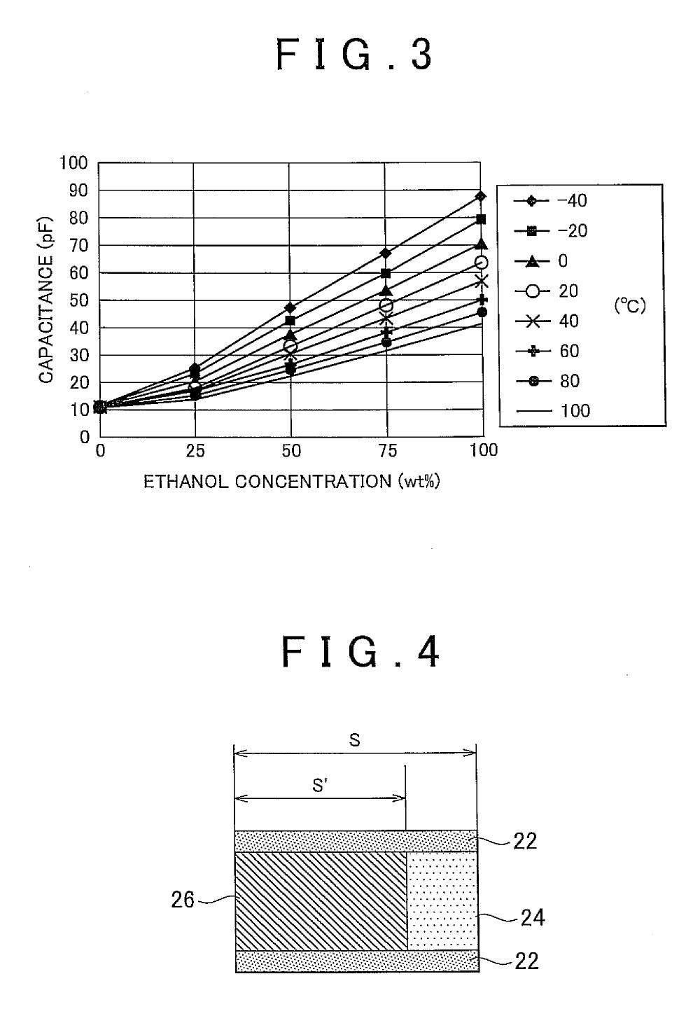

The alcohol concentration sensor 12 is a capacitance-type alcohol concentration sensor. Hereinafter, the detection principle of the capacitance-type alcohol concentration sensor will be described. FIG. 2 is a view showing a frame format of the fundamental structure for detecting an alcohol concentration of the alcohol concentration sensor 12. The structure in FIG. 2 will be referred to as a detecting portion 20 of the alcohol concentration sensor 12 for the sake of convenience. This detecting portion 20 has two electrodes 22 provided in opposing positions that are separated by an interelectrode distance d. Each electrode 22 has a surface area S. An output indicative of the capacitance C=ε×S/d from the detecting portion 20 is detected according to the permittivity E of the fuel between the two electrodes 22. The value of the detected capacitance C changes according to the interelectrode distance d, the electrode surface area S, the permittivity E of the interelectrode material, i.e., the fuel, and the temperature of the fuel. FIG. 3 is a chart showing the temperature characteristic of the ethanol concentration and the capacitance value. The capacitance value (pF) becomes larger as the temperature of the fuel decreases. The temperature characteristic of the relative permittivity and the permittivity is a specific value according to the material.

In the first example embodiment, a map corresponding to the capacitance value and the fuel temperature is created according to the temperature characteristic shown in FIG. 3. This map is stored in the control apparatus 14. In the first example embodiment, the alcohol concentration sensor 12 is provided with a temperature sensor capable of detecting the temperature of the fuel at the detecting portion 20. Incidentally, this temperature sensor is not limited as long as it is configured to be able to identify the temperature of the fuel at the detecting portion 20. This temperature sensor may also be mounted to the inside or the outside of the alcohol concentration sensor 12. Also, any of various known technologies, such as technology that estimates the temperature of the fuel, may also be used as an alternative to directly detecting the temperature of the fuel with a temperature sensor. The ethanol concentration of the fuel is calculated based on the capacitance value and the fuel temperature detected via the detecting portion 20, by referencing a map, so even if the obtained fuel temperatures are different, the ethanol concentration of the fuel can be calculated from the sensor output value of the alcohol concentration sensor 12 after correcting for the amount of temperature characteristic of the capacitance value.

One conceivable failure mode of the capacitance-type alcohol concentration sensor 12 is a decrease in the electrode surface area S due to corrosion of the electrodes 22 or foreign matter adhered to the electrodes 22. FIG. 4 is a view showing a frame format of one such example of a failure mode of a capacitance-type alcohol concentration sensor. In FIG. 4, in addition to fuel 26, foreign matter 24 (such as a gum component, for example) is adhered between the two electrodes 22. In this case, the electrode surface area is essentially reduced from S to S′, so even if the fuel has the same ethanol concentration, the capacitance C detected by the detecting portion 20 indicates a small value. Also, if the foreign matter adhered to the electrodes 22 is dielectric material, capacitance that includes that foreign matter is indicated as the output of the alcohol concentration sensor 12. As a result, a value that differs from the correct ethanol concentration ends up being conveyed to the control apparatus 14.

Therefore, in the first example embodiment, a failure mode such as that illustrated in FIG. 4 is detected by the method described below.

With the capacitance-type alcohol concentration sensor 12, the capacitance has a temperature characteristic, as shown in FIG. 3. If the alcohol concentration sensor 12 is indicating an output value correctly, then when the ethanol concentration of the fuel is the same, the same output value indicative of the ethanol concentration should be obtained from the alcohol concentration sensor 12 even if the temperature of the fuel is different. Therefore, in an environment in which the ethanol concentration is constant, if the alcohol concentration sensor 12 is outputting a correct value corresponding to the ethanol concentration, the ethanol concentration that is ultimately obtained after the capacitance value has been corrected according to the temperature characteristic should be the same value.

An abnormality determination for the alcohol concentration sensor 12 is performed using this point. First, a plurality of capacitance values at different obtained fuel temperatures are obtained. Then an ethanol concentration of the fuel to be measured is obtained from each of these capacitance values after correcting for the amount of change in the capacitance value due to the temperature characteristic. As described above, in the first example embodiment, the temperature characteristic is corrected according to the map stored in the control apparatus 14. If the difference of the obtained ethanol concentration is equal to or greater than a predetermined value, it is determined that there is an abnormality in the alcohol concentration sensor 12.

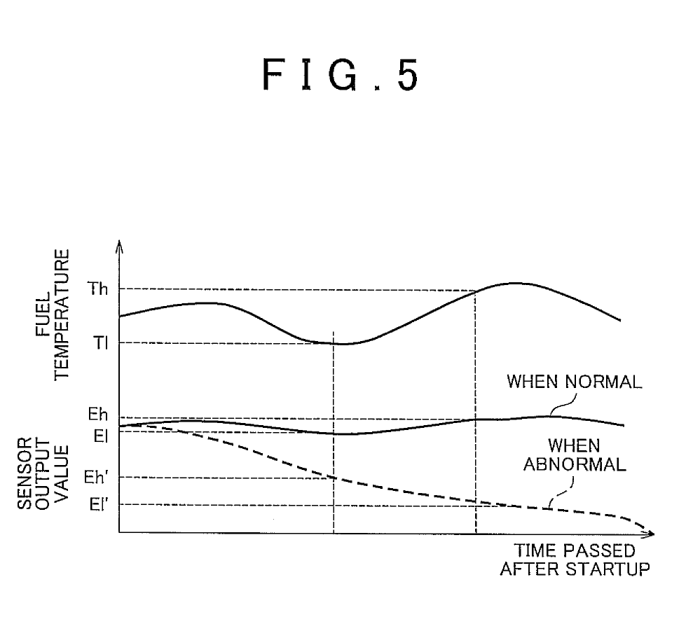

FIG. 5 is a more detailed view showing a frame format of the method for determining an abnormality of the alcohol concentration sensor 12 according to the first example embodiment. As shown in FIG. 5, if the failure mode described above has not occurred in the alcohol concentration sensor 12, the sensor output value will indicate a change corresponding to the fuel temperature, as indicated by the “WHEN NORMAL” line (i.e., the lower solid line) in FIG. 5. This is because the capacitance value obtained via the alcohol concentration sensor 12 has a temperature characteristic, as described above. If, on the other hand, an abnormality has occurred, the sensor output value will indicate a change that does not correspond to the fuel temperature, as indicated by the “WHEN ABNORMAL” line (i.e., the broken line) in FIG. 5.

In FIG. 5, Th indicates the maximum value of the fuel temperature, Tl indicates the minimum value of the fuel temperature, Eh indicates the output value of the alcohol concentration sensor 12 when the fuel temperature is Th, and El indicates the output value of the alcohol concentration sensor 12 when the fuel temperature is Tl. The minimum temperature Tl after startup of the internal combustion engine, the sensor output value (ethanol concentration) El at Tl, the maximum temperature Th, and the sensor output value (ethanol concentration) Eh at Th are all stored in the control apparatus 14. A failure diagnosis is made using a sensor output value at which the obtained fuel temperature differs by a somewhat large amount when the temperature difference Th−Tl is equal to or greater than a predetermined value Ts.

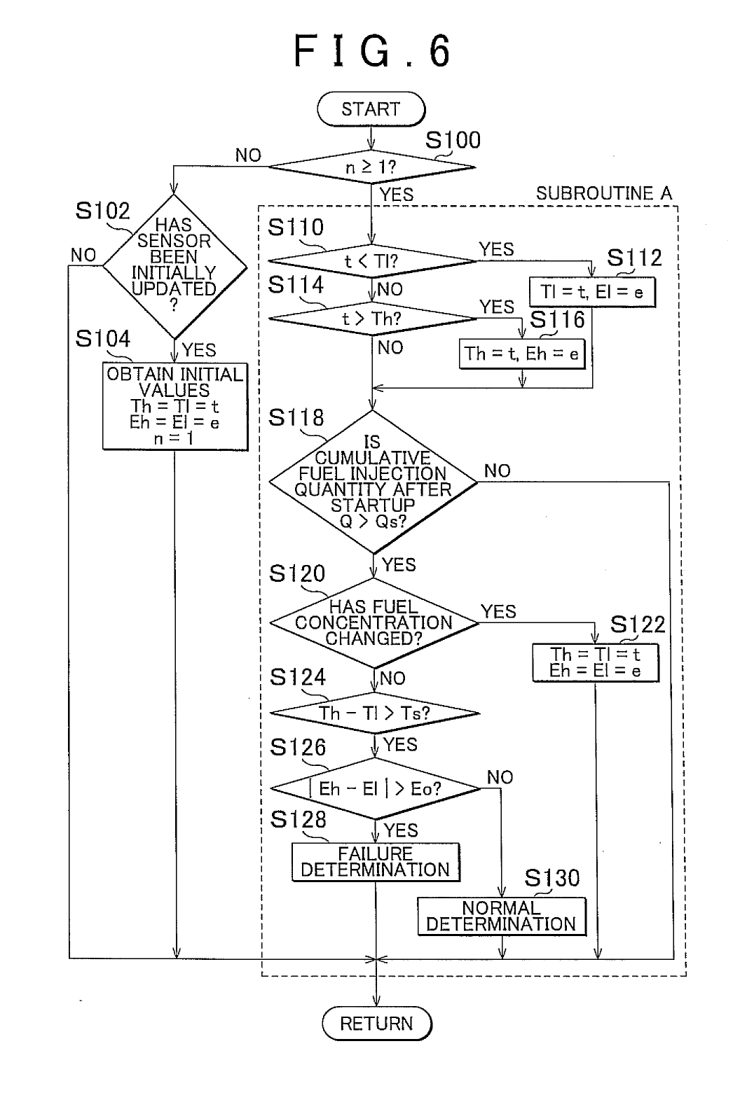

FIG. 6 is a flowchart of a routine executed by the control apparatus 14 in the first example embodiment of the invention. In the routine in FIG. 6, the letter t refers to the fuel temperature, the letter e refers to the sensor output value (i.e., the ethanol concentration) of the alcohol concentration sensor 12, the letter n refers to a counter value, the letter Q refers to the cumulative fuel injection quantity (or the amount of fuel movement) after startup, the letters Qs refer to the cumulative injection quantity for making a fuel concentration stability determination, the letters Ts refer to a temperature difference that initiates an abnormality determination, and the letters Eo refer to a determining value that determines a change in the output when there is an abnormality.

In the routine shown in FIG. 6, it is first determined whether the counter value n is equal to or greater than 1 (step S100). In this step, the value of a counter value n that has been set beforehand in the control apparatus 14 is compared to 1. The counter value n is set to zero when the internal combustion engine is started.

If it is determined in step S100 that the counter value n is not equal to or greater than 1, it is then determined whether the sensor has been initially updated (step S102). This step checks whether activation of the alcohol concentration sensor 12 is complete. For example, it is determined whether sufficient time for activating the alcohol concentration sensor 12 has passed or whether an output signal from the alcohol concentration sensor 12 to the control apparatus 14 is coming across normally. If the determination in step S102 is no, this cycle of the routine ends and the process returns.

If, on the other hand, the determination in step S102 is yes, then initial values of the sensor output values are obtained (step S104). In this step, the current fuel temperature t is set to Th and Tl (Th=Ti=t), the current sensor output e is set to Eh and El(Eh=El=e), and 1 is substituted into the counter, after which the process returns.

Then after the initial values have been obtained, step S100 is performed again, and steps S110 and thereafter are performed. In step S110, it is determined whether t<Tl. If the determination is yes, i.e., if t<Tl, then Tl is set equal to t (i.e., Tl =1) and El is set equal to e (i.e., El=e) in step S112. If, on the other hand, the determination in step S110 is no, then it is determined whether T>Th in step S114. If the determination is yes, i.e., if T>Th, then Th is set equal to t (i.e., Th=t) and Eh is set equal to e (i.e., Eh=e) in step S116.

Then it is determined whether a cumulative fuel injection quantity Q after startup is greater than a preset cumulative injection quantity Qs for making a fuel concentration stability determination (step S118). If the determination in this step is no (i.e., if the cumulative fuel injection quantity Q after startup is not greater than the preset cumulative injection quantity Qs), the process returns.

If, on the other hand, the determination in step S118 is yes, i.e., if Q>Qs, it is then determined whether the concentration of the fuel has changed (step S120). In this step, a determination is made as to whether the ethanol concentration of the fuel measured at the alcohol concentration sensor 12 has changed.

This determination can be made, for example, by any one or a combination of two or more of the following methods. (1) Determining whether fuel is being supplied; (1-1) It is determined that the fuel concentration has not changed if there has been no change in the amount of fuel remaining in the fuel tank 4. (1-2) It is determined that the fuel concentration has not changed if a fuel cap, not shown, of the fuel tank 4 has not been opened or closed. (2) Determining whether the fuel concentration has changed; (2-1) It is determined that the fuel concentration has not changed if there has been no change in the ethanol concentration detected by the alcohol concentration sensor 12 at a given temperature, i.e., at the same temperature. Alternatively, it is determined that the fuel concentration has not changed if the ethanol concentration detected by the alcohol concentration sensor 12 indicates a constant change in an environment in which a temperature change is constant. (2-2) It is determined that the fuel concentration has not changed if there has not been a large change in the air-fuel ratio that is controlled by the current ethanol concentration while the internal combustion engine is operating steadily. (2-3) It is determined the fuel concentration has changed if the cumulative amount of fuel movement or the cumulative injection quantity from the injectors 2 since the last fueling is equal to or greater than a predetermined value. This can be determined based on the cumulative value of the fuel injection quantity of the injectors 2 or the detection results of the fuel flowrate, for example. For example, any of a variety of known technologies may be used, e.g., the driving amount of the fuel pump 8 may be used.

Incidentally, it takes time for the concentration at the location of the alcohol concentration sensor 12 and the fuel inside a delivery pipe, not shown, that is arranged in a fuel line 6 to actually change after fueling. Therefore, it is preferable to check whether the concentration has changed and make a failure diagnosis after the cumulative injection quantity after startup has risen above a certain level. This is why it the determination as to whether Q>Qs is made in step S118 in the first example embodiment.

If it is determined in step S120 that the concentration of the fuel has changed, the process proceeds on to step S122. If the concentration of the fuel has changed, then the environment is unsuitable for making the abnormality determination for the alcohol concentration sensor 12 according to the first example embodiment, so the abnormality determination is not made. Therefore, in step S122, Th is set equal to Tl and t (i.e., Th=Tl=t) and Eh is set equal to El and e (i.e., Eh=El=e), and the process returns.

If, on the other hand, it is determined in step S120 that the concentration of the fuel has not changed, it is then determined whether Th−Tl>Ts (step S124). That is, it is determined whether the difference between the maximum value of the fuel temperature and the minimum value of the fuel temperature is greater than a predetermined abnormality determination starting temperature difference Ts. If a change in temperature of equal to or greater than this Ts is not obtained, the abnormality determination for the alcohol concentration sensor 12 is suspended, and the process returns.

If the determination in step S124 is yes, i.e., if Th-Tl >Ts, it is then determined whether |Eh−El|>Eo (step S126). That is, it is determined whether the absolute value of the difference between the sensor output value Eh at Th (i.e., when the fuel temperature is highest) and the sensor output value El at Tl (i.e., when the fuel temperature is lowest) is large enough to exceed a determining value Eo.

Referring back to FIG. 5, when the alcohol concentration sensor 12 is abnormal, the value of |Eh-El| becomes a value |Eh−El| that is larger than normal. Therefore, whether the alcohol concentration sensor 12 is abnormal can be determined using the above determining expression (i.e., |Eh−El|>Eo), by setting the value of Eo in an environment in which the alcohol concentration sensor 12 is normal as a reference value beforehand.

If the determination in step S126 is no, then it is determined that the alcohol concentration sensor 12 is normal (step S130). If, on the other hand, the determination in step S126 is yes, then it is determined that a failure has occurred in the alcohol concentration sensor 12 (step S128).

Incidentally, in the first example embodiment described above, the alcohol concentration sensor 12 corresponds to the fuel property sensor of the invention, the fuel temperature identifying portion of the invention is realized by the value of the fuel temperature t being obtained in the control apparatus 14, the obtaining portion of the invention is realized by the processes in steps S104 and S122 described above being performed in the control apparatus 14, and the determining portion of the invention is realized by steps S126, S128, and S130 described above being performed in the control apparatus 14.

Incidentally, methods of diagnosing a failure in a capacitance-type fuel property sensor according to related art will now be described. There is a method to detect whether there is an abnormality based on whether an output fluctuation amount (i.e., the amount of fluctuation in a detection value) of an alcohol concentration sensor while an internal combustion engine is operating is greater than an abnormality determining value. However, with this method, the output of the sensor changes when the alcohol concentration changes. Therefore, in order to prevent an erroneous detection, the abnormality determining value must be a relatively large value. However, if the abnormality determining value is a large value, it becomes difficult to detect an abnormality in which the abnormality level is small, as is the case with deterioration.

There is also a method for determining an abnormality of an alcohol concentration sensor, which involves estimating the alcohol concentration of the fuel based on the air-fuel ratio feedback control state, torque fluctuation, and rotation speed fluctuation and the like, and then making the abnormality determination based on the difference between this estimated value and the detection value of the alcohol concentration sensor. However, with this method, the abnormality detection of the alcohol concentration sensor is made indirectly using a sensor other than the alcohol concentration sensor, so detection may be affected by a disturbance, thus making it difficult to accurately detect an abnormality. This is why in the first example embodiment, the abnormality determination for the alcohol concentration sensor 12 itself is made using only the output of the alcohol concentration sensor 12. Therefore, detection is not affected by a disturbance because no other sensor is used, so a failure mode in which the relative abnormality level is small, as is the case with deterioration of the alcohol concentration sensor or the like, can also be accurately detected.

### Modified Example of the First Example Embodiment

In the first example embodiment, the abnormality determination according to the first example embodiment of the invention is applied to the capacitance-type alcohol concentration sensor 12. However, the invention is not limited to this. The abnormality determination according to the first example embodiment may also be applied to any of a variety of types of capacitance-type fuel property sensors.

In the first example embodiment, the alcohol concentration sensor 12 is provided in the fuel line 6. However, the invention is not limited to this. That is, the alcohol concentration sensor 12 may also be provided in the fuel tank 4 instead of in the fuel line 6.

Incidentally, in the first example embodiment, the abnormality determination for the alcohol concentration sensor is made by using the ethanol concentrations identified based on the output of the alcohol concentration sensor 12 and comparing the difference between those concentrations with a predetermined value. However, the invention is not limited to this. That is, it may also be determined whether the capacitance value itself that is detected by the detecting portion 20 of the alcohol concentration sensor 12 follows the temperature characteristic when the alcohol concentration sensor 12 is functioning normally. For example, the temperature characteristic may be specified in advance from design values, testing, simulation, or the like, and it may be determined whether the capacitance value follows this temperature characteristic.

### Second Example Embodiment

A second example embodiment of the invention has the same hardware structure as the first example embodiment shown in FIG. 1. In the second example embodiment, the sensor output value obtained in the routine shown in FIG. 6 in the first example embodiment is obtained immediately before the internal combustion engine 10 stops, and immediately after the internal combustion engine 10 is started after a certain amount of time has passed after the internal combustion engine 10 is stopped (i.e., immediately after the internal combustion engine 10 is restarted following a period of being stopped for a certain amount of time). As a result, sensor output values at different fuel temperatures can be obtained for the absolute same fuel. Thus, detection accuracy can be improved and the number of times that detection is performed can be ensured.

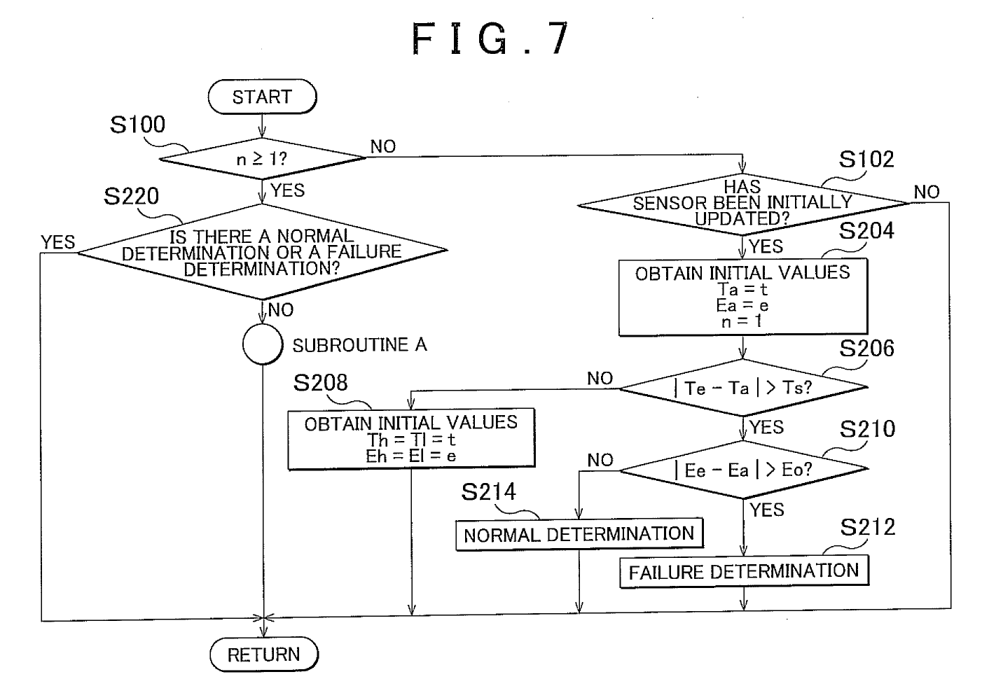

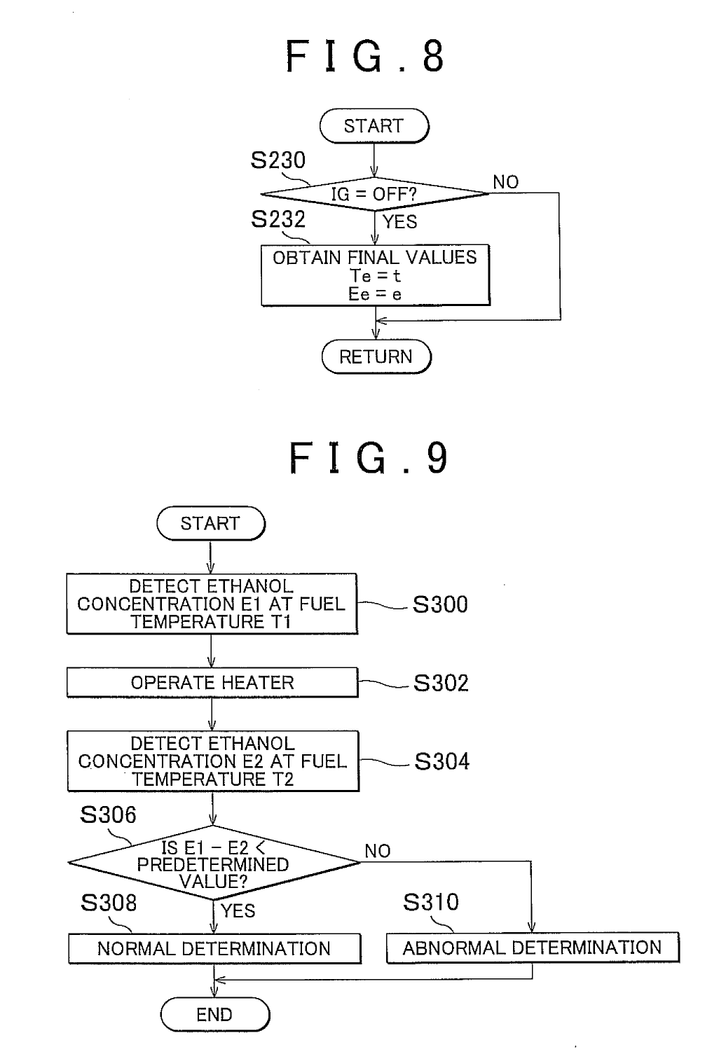

FIGS. 7 and 8 are flowcharts of routines executed by the control apparatus 14 in the second example embodiment. In the second example embodiment, the shut-off routine shown in FIG. 8 is executed when the internal combustion engine 10 is shut off (i.e., stopped). Then the routine shown in FIG. 7 is executed when the internal combustion engine 10 is started, or immediately after the internal combustion engine 10 is started, after the internal combustion engine 10 has been stopped for a certain amount of time. Incidentally, whether the internal combustion engine 10 has been stopped for a certain amount of time may be determined, for example, by the initial fuel temperature after the routine in FIG. 7 starts. In the routines in FIGS. 7 and 8, the letters Ta refer to the initial fuel temperature, the letters Ea refer to the initial sensor output, the letters Te refer to the last final fuel temperature, and the letters Ee refer to the last final sensor output.

In the routine in FIG. 7, first step S100 is performed, just as in the first example embodiment.

If the determination in step S100 is no, then step S102 is performed, just as in the first example embodiment. If the determination in step S102 is no, the process returns, just as in the first example embodiment.

If the determination in step S102 is yes, then initial values are obtained in this second example embodiment (step S204). That is, the current t is obtained as the initial fuel temperature Ta and the current e is obtained as the initial sensor output Ea. In conjunction with this, the counter value n is set to 1.

Next, it is determined whether |Te−Ta|>Ts (step S206). Here, Te is the value obtained according to the routine in FIG. 8. That is, in the routine in FIG. 8, when the ignition IG is off (IG=OFF) when the internal combustion engine 10 is stopped (step S230), t and e at that time are obtained as final values Te and Ee, respectively (step S232). Of these values, the value of Te is used in step S206.

If the determination in step S206 is no, the process proceeds on to step S208 and the initial values are obtained. That is, t at that time is set to Th and Tl, and e at that time is set to Eh and El. Then the process returns.

If, on the other hand, the determination in step S206 is yes, the process proceeds on to step S210. In step S210, it is determined whether |Ee−Ea|>Eo. If this determination is yes, it is determined that there is a failure in the alcohol concentration sensor 12 (step S212). If, on the other hand, this determination is no, it is determined that the alcohol concentration sensor 12 is normal (step S214). Accordingly, an abnormality determination for the alcohol concentration sensor 12 can be made just as in step S126 in the routine shown in FIG. 6 of the first example embodiment.

On the other hand, if the determination in step S100 is yes, it is determined whether there is a normal determination or an abnormal determination (step S220). If a determination result, i.e., either a normal determination or an abnormal determination, has been obtained, this cycle of the routine ends. If no determination result has been obtained, the process proceeds on to subroutine A. Subroutine A is a routine (steps S110 to S130) for the portion encircled by the broken line in the flowchart in FIG. 6. Accordingly, an abnormality determination for the alcohol concentration sensor 12 can be made, just as in the first example embodiment.

### Third Example Embodiment

A third example embodiment of the invention has a hardware structure similar to the hardware structure of the first example embodiment except that a heater is housed in the alcohol concentration sensor 12. Operating the heater enables the temperature of the fuel at the detecting portion 20 to be freely heated to a desired temperature at a desired time. Incidentally, as a modified example of the third example embodiment, a separate heater may be provided outside the alcohol concentration sensor 12. In this case, the heater may be provided upstream of the alcohol concentration sensor 12 in the fuel line 6 such that the fuel temperature at the location of the alcohol concentration sensor 12 can be adjusted to a desired value.

### Fourth Example Embodiment

A system according to a fourth example embodiment of the invention has the same hardware structure as the third example embodiment. FIG. 9 is a flowchart of a routine executed by the control apparatus 14 in the fourth example embodiment of the invention. According to the routine in FIG. 9, the fuel temperature can be increased by operating the heater, and a plurality of capacitance values at different obtained fuel temperatures can be obtained. Forcibly changing the temperature with heat from the heater is beneficial for ensuring a detection opportunity and also improves detection accuracy. Incidentally, in the routine in FIG. 9, the ethanol concentration is detected.

In the routine in FIG. 9, first the ethanol concentration E1 at a fuel temperature T1 is detected (step S300). Then the heater is operated (i.e., turned on) (step S302) and the ethanol concentration E2 at a fuel temperature T2(T2>T1) is detected (step S304).

Continuing on, it is determined whether the value of E1−E2 is less than a predetermined value (step S306). If the determination is yes, the difference between E1−E2 is less than the predetermined value, so it can be determined that the deviation of the output value of the ethanol concentration corresponding to the temperature change is small. In this case, a determination of normal is made (step S308), and this cycle of the routine ends.

If, on the other hand, the determination in step S306 is no, the difference between E1−E2 is equal to or greater than the predetermined value, so it can be determined that the deviation of the output value of the ethanol concentration corresponding to the temperature change is large. In this case, a determination of abnormal is made (step S310), and this cycle of the routine ends.

### Fifth Example Embodiment

A system according to a fifth example embodiment of the invention has the same hardware structure as the third example embodiment, and is configured to be able to execute the sensor abnormality determining routine according to the fourth example embodiment (i.e., the routine in FIG. 9).

In the fifth example embodiment, the heater is operated and an abnormality determination for the alcohol concentration sensor 12 is made, under a predetermined condition that it can be determined that the fuel property is stable. More specifically, in this example embodiment, it is determined that fuel property is stable by determining whether any one or two or more of the following conditions is (are) satisfied. (i) A change in the ethanol concentration is not able to be confirmed for a predetermined period of time or longer. (ii) The fuel tank 4 has not just been filled with fuel. (iii) A predetermined period of time has passed after the internal combustion engine 10 has started.

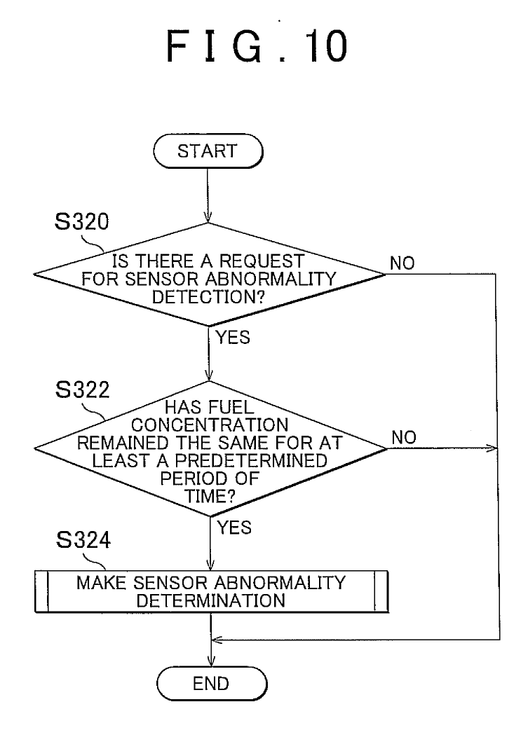

FIG. 10 is a flowchart of a routine executed by the control apparatus 14 in the fifth example embodiment of the invention. In the routine in FIG. 10, first it is determined whether there is a request to detect fuel flowing between the electrodes (step S320). If there is no such request, this cycle of the routine ends.

Continuing on, it is determined whether there has been no change in the fuel concentration (i.e., whether the fuel concentration has remained the same) for a predetermined period of time or longer (step S322). In this step, it is determined whether the fuel concentration has changed by making any one or two or more of the determinations (i) to (iii) described above. For example, if the fluctuation range of the fuel concentration remains within a predetermined extremely small range for a certain preset period of time, it is determined that there is no change in the fuel concentration. If the determination in this step is no, the fuel concentration is changing, so the environment is unsuitable for making an abnormality determination for the alcohol concentration sensor 12. Therefore, this cycle of the routine ends.

If, on the other hand, the determination in step S322 is yes, an abnormality determination for the alcohol concentration sensor 12 is made (step S324). In this step, the routine according to the fourth example embodiment shown in FIG. 9 is executed. Accordingly, an abnormality determination for the alcohol concentration sensor 12 is able to be made.

### Sixth Example Embodiment

A system according to a sixth example embodiment of the invention has the same hardware structure as the third example embodiment, and is configured to be able to execute the sensor abnormality determining routine according to the fourth example embodiment (i.e., the routine in FIG. 9).

In the sixth example embodiment, an abnormality determination for the alcohol concentration sensor 12 is made while the system that includes the internal combustion engine 10 is stopped. While the internal combustion engine is stopped, no fuel is consumed (i.e., no fuel moves around the alcohol concentration sensor 12). Therefore, the fuel property at the detecting portion 20 will not change regardless of whether the fuel tank 4 is being filled with a different type of fuel. Thus the sixth example embodiment focuses on a case in which the fuel property is constant in this way, and makes an abnormality determination for a fuel property sensor while the internal combustion engine is stopped, by actively changing the fuel temperature by operating the heater.

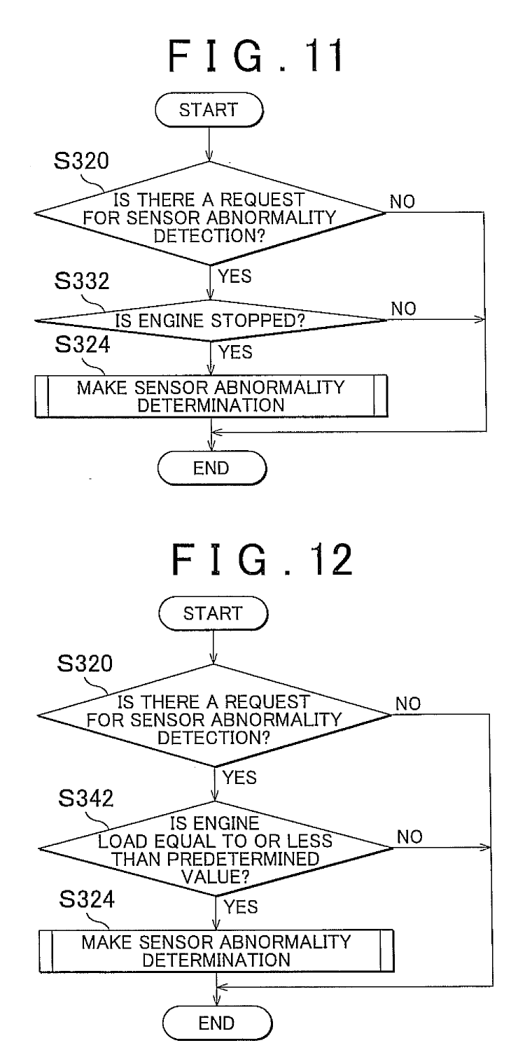

FIG. 11 is a flowchart of a routine executed by the control apparatus 14 in the sixth example embodiment of the invention. In the routine in FIG. 11, first it is determined whether there is a request to detect fuel flowing between the electrodes (step S320). If there is no such request, this cycle of the routine ends.

Continuing on, it is determined whether operation of the system that includes the internal combustion engine 10 is currently stopped (step S322). Here, in this example embodiment, operation is considered to be stopped, for example, before a conventional engine is started, after a conventional engine is stopped, and while a hybrid engine is stopped. If the determination in this step is no, this cycle of the routine ends.

If, on the other hand, the determination in step S322 is yes, then the same abnormality determination that is made in the fifth example embodiment is made for the alcohol concentration sensor 12 (step S324). Accordingly, an abnormality determination for the alcohol concentration sensor 12 can be made.

### Seventh Example Embodiment

A system according to the seventh example embodiment of the invention has the same hardware structure as the third example embodiment, and is configured to be able to execute a sensor abnormality determining routine according to the fourth example embodiment (i.e., the routine in FIG. 9).

In the seventh example embodiment, a heater is operated and an abnormality determination for the alcohol concentration sensor 12 is made when the engine load is equal to or less than a predetermined value. If the fuel temperature rises when the internal combustion engine main body 10 is operating with a high load, problems such as knock or vapor lock may occur. The seventh example embodiment makes it possible to inhibit the occurrence of such problems.

FIG. 12 is a flowchart of a routine executed by the control apparatus 14 in the seventh example embodiment of the invention. In the routine in FIG. 12, first it is determined whether there is a request to detect fuel flowing between the electrodes, just as in the fifth example embodiment (step S320). If there is no such request, this cycle of the routine ends.

Continuing on, it is determined whether a load of the internal combustion engine 10 is currently equal to or less than a predetermined value (step S342). The load may be detected using any one of a variety of known technologies for detecting a load of an internal combustion engine, such as the throttle valve opening amount or the like. Here, the set predetermined value may be set as the value of a load at which there is no possibility of problems such as knock or vapor lock occurring even if the fuel temperature rises. If the determination in this step is no, then this cycle of the routine ends.

If, on the other hand, the determination in step S342 is yes, then the same abnormality determination that is made in the fifth example embodiment is made for the alcohol concentration sensor 12 (step S324). Accordingly, an abnormality determination for the alcohol concentration sensor 12 can be made.

Incidentally, the seventh example embodiment is also able to benefit from the advantages described below. That is, the fuel temperature can be effectively raised with only a small amount of power to the heater, so only a small amount of power is consumed. Also, the amount of fuel movement is small so it is unlikely that the fuel property will change while an abnormality determination is being made. In order to benefit from these advantages, the predetermined value in step S342 may also be set beforehand to a value that corresponds to a load at which the amount of power consumed is equal to or less than a predetermined amount, or a value that corresponds to a load at which the amount of fuel movement is sufficiently small compared to the time that it takes to make an abnormality determination (e.g., compared to the time that is takes to change the temperature with the heater).

While various example embodiments for carrying out the invention have been described with reference to the drawings, the invention may also be described in the manner below.

A first aspect of the invention relates to an abnormality determining device that determines an abnormality of a capacitance-type fuel property sensor having a detecting portion that detects a capacitance value of fuel to be measured. This abnormality determining device includes a fuel temperature identifying portion that obtains a temperature of the fuel to be measured at the detecting portion; an obtaining portion that obtains a plurality of the capacitance values of the fuel to be measured, in which a property of fuel at the detecting portion is substantially the same or can be presumed to be substantially the same, at different obtained temperatures of the fuel to be measured; and a determining portion that determines whether there is an abnormality in the fuel property sensor based on whether the plurality of capacitance values obtained by the obtaining portion are following a temperature characteristic of a capacitance value at the fuel property sensor.

According to this aspect, it is possible to determine whether an abnormality in which a correct value corresponding to a fuel property is unable to be output is occurring in a fuel property sensor, using the fact that a capacitance value has a temperature characteristic.

Also, the obtaining portion may include a first obtaining portion that obtains a first capacitance value when the temperature of the fuel to be measured is a first temperature, and a second obtaining portion that obtains a second capacitance value when i) the temperature of the fuel to be measured is a second temperature that differs from the first temperature, and ii) a fuel property at the detecting portion is the same as the fuel property when the first capacitance value is obtained, or a difference between the fuel property when the first capacitance value is obtained and the fuel property at the detecting portion is within a predetermined range. Also, the determining portion may include a corrected property value obtaining portion that obtains a value of a fuel property corresponding to the first capacitance value after correcting for an amount of change due to the temperature characteristic in the capacitance value of the fuel property sensor corresponding to the temperature of the fuel to be measured, and a value of a fuel property corresponding to the second capacitance value after correcting for an amount of change due to the temperature characteristic in the capacitance value of the fuel property sensor corresponding to the temperature of the fuel to be measured, and a portion that determines whether there is an abnormality in the fuel property sensor based on a comparison of the plurality of fuel properties obtained by the corrected property value obtaining portion.

With this kind of structure, a plurality of capacitance values at different obtained temperatures can be obtained. Properties of the fuel to be measured can be obtained from these capacitance values, after correcting for the change in the capacitance value due to the temperature characteristic. Then it can be determined whether an abnormality in which a correct value corresponding to the fuel property is unable to be output is occurring in the fuel property sensor, by comparing the obtained properties. If the fuel property sensor is indicating output values that correctly follow the temperature characteristic, when the property of the fuel being measured is the same, output values indicative of the same property should be obtained from the fuel property sensor even if the temperature of the fuel being measured is different.

Also, the determining portion may determine that there is an abnormality in the fuel property sensor when a difference among the plurality of fuel properties obtained by the corrected property value obtaining portion is larger than a predetermined value. Accordingly, it is possible to detect when the fuel property obtained from the plurality of capacitance values at different obtained fuel temperatures exceeds the predetermined value and deviates largely.

Also, the obtaining portion may include a shut-off obtaining portion that obtains the capacitance value when an internal combustion engine is shut off, and a startup obtaining portion that obtains the capacitance value the next time the internal combustion engine is started after the internal combustion engine has been shut off. Also, the determining portion may determine whether there is an abnormality in the fuel property sensor based on whether a value of a fuel property detected based on the capacitance value obtained by the shut-off obtaining portion and a value of a fuel property detected based on the capacitance value obtained by the startup obtaining portion are following the temperature characteristic of the capacitance value of the fuel property sensor. This kind of structure makes it possible to obtain sensor output values at different fuel temperatures for fuel of the absolute same property.

Also, the abnormality determining device may also include a temperature adjusting apparatus capable of changing the temperature of the fuel to be measured that is measured by the fuel property sensor. Accordingly, the temperature of the fuel to be measured can be changed.

Also, the temperature adjusting apparatus may include at least one of a heater provided inside the fuel property sensor, or a heater that is provided outside the fuel property sensor, upstream of the fuel property sensor, and capable of heating fuel that flows toward the fuel property sensor. Operating the heater enables the temperature of the fuel to be measured to be increased.

Also, the fuel property sensor may be provided in a fuel supply system of an internal combustion engine, and the obtaining portion may include a heating control portion that heats the fuel to be measured that is measured by the fuel property sensor by the temperature adjusting apparatus when a load of the internal combustion engine is equal to or less than a predetermined value while the internal combustion engine is operating, and a low load obtaining portion that obtains the capacitance value from the fuel property sensor when the temperature of the fuel to be measured has been changed by the heating control portion. With this kind of structure, the abnormality determination for a fuel property sensor according to the invention is able to be made while avoiding problems that occur when fuel is heated when the internal combustion engine is operating with a high load.

While the invention has been described with reference to example embodiments thereof, it is to be understood that the invention is not limited to the described embodiments or constructions. To the contrary, the invention is intended to cover various modifications and equivalent arrangements. In addition, while the various elements of the example embodiments are shown in various combinations and configurations, other combinations and configurations, including more, less or only a single element, are also within the scope of the invention.

What is claimed is:

1. An abnormality determining device that determines an abnormality of a capacitance-type fuel property sensor having a detecting portion that detects a capacitance value of fuel to be measured, comprising:
a fuel temperature identifying portion that obtains a temperature of the fuel to be measured at the detecting portion;
an obtaining portion that obtains a plurality of the capacitance values of the fuel to be measured, in which a property of fuel at the detecting portion is substantially the same or can be presumed to be substantially the same, at different obtained temperatures of the fuel to be measured; and
a determining portion that determines whether there is an abnormality in the fuel property sensor based on whether the plurality of capacitance values obtained by the obtaining portion are following a temperature characteristic of a capacitance value at the fuel property sensor.

2. The abnormality determining device according to claim 1, wherein the obtaining portion includes a first obtaining portion that obtains a first capacitance value when the temperature of the fuel to be measured is a first temperature, and a second obtaining portion that obtains a second capacitance value when i) the temperature of the fuel to be measured is a second temperature that differs from the first temperature, and ii) a fuel property at the detecting portion is the same as the fuel property when the first capacitance value is obtained, or a difference between the fuel property when the first capacitance value is obtained and the fuel property at the detecting portion is within a predetermined range; and the determining portion includes a corrected property value obtaining portion that obtains a value of a fuel property corresponding to the first capacitance value after correcting for an amount of change due to the temperature characteristic in the capacitance value of the fuel property sensor corresponding to the temperature of the fuel to be measured, and a value of a fuel property corresponding to the second capacitance value after correcting for an amount of change due to the temperature characteristic in the capacitance value of the fuel property sensor corresponding to the temperature of the fuel to be measured, and a portion that determines whether there is an abnormality in the fuel property sensor based on a comparison of the plurality of fuel properties obtained by the corrected property value obtaining portion.

3. The abnormality determining device according to claim 2, wherein the determining portion determines that there is an abnormality in the fuel property sensor when a difference among the plurality of fuel properties obtained by the corrected property value obtaining portion is larger than a predetermined value.

4. The abnormality determining device according to claim 1, wherein the obtaining portion includes a shut-off obtaining portion that obtains the capacitance value when an internal combustion engine is shut off, and a startup obtaining portion that obtains the capacitance value the next time the internal combustion engine is started after the internal combustion engine has been shut off; and the determining portion determines whether there is an abnormality in the fuel property sensor based on whether a value of a fuel property detected based on the capacitance value obtained by the shut-off obtaining portion and a value of a fuel property detected based on the capacitance value obtained by the startup obtaining portion are following the temperature characteristic of the capacitance value of the fuel property sensor.

5. The abnormality determining device according to claim 1, further comprising a temperature adjusting apparatus capable of changing the temperature of the fuel to be measured that is measured by the fuel property sensor.

6. The abnormality determining device according to claim 5, wherein the temperature adjusting apparatus includes at least one of a heater provided inside the fuel property sensor, or a heater that is provided outside the fuel property sensor, upstream of the fuel property sensor, and capable of heating fuel that flows toward the fuel property sensor.

7. The abnormality determining device according to claim 5, wherein the obtaining portion includes a heating control portion that heats the fuel to be measured that is measured by the fuel property sensor by the temperature adjusting apparatus when a load of an internal combustion engine is equal to or less than a predetermined value while the internal combustion engine is operating, and a low load obtaining portion that obtains the capacitance value from the fuel property sensor when the temperature of the fuel to be measured has been changed by the heating control portion.

8. An abnormality determining method for determining an abnormality of a capacitance-type fuel property sensor that has a detecting portion that detects a capacitance value of fuel to be measured, comprising:
obtaining a temperature of the fuel to be measured at the detecting portion;
obtaining a plurality of the capacitance values at different obtained temperatures of the fuel to be measured; and
determining whether there is an abnormality in the fuel property sensor based on whether the obtained plurality of capacitance values are following a temperature characteristic of a capacitance value at the fuel property sensor.

9. The abnormality determining method according to claim 8, further comprising determining whether a property of the fuel at the detecting portion is substantially the same each time each of the plurality of capacitance values is obtained.
